(19) United States
(12) Patent Application Publication
(10) Pub. No.: US 2024/0250128 A1
(43) Pub. Date: Jul. 25, 2024

(54) SILICON CARBIDE SUBSTRATE, SILICON CARBIDE WAFER, AND SILICON CARBIDE SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventor: HIDEYUKI UEHIGASHI, Nisshin-shi (JP)

(21) Appl. No.: 18/521,014

(22) Filed: Nov. 28, 2023

(30) Foreign Application Priority Data
Jan. 23, 2023 (JP) 2023-008286

(51) Int. Cl. H01L 29/16; H01L 29/10; H01L 29/36; H01L 29/78

(52) U.S. Cl. CPC H01L 29/1608; H01L 29/1045; H01L 29/36; H01L 29/7813

(57) ABSTRACT

A silicon carbide substrate includes a substrate made of silicon carbide and having a Young's modulus of 475 GPa or more at 500° C. measured by a resonance method. A silicon carbide wafer includes: the silicon carbide substrate; and an epitaxial layer formed on the silicon carbide substrate. The epitaxial layer has a thickness within a range of 4 to 40 μm. A silicon carbide semiconductor device includes: the silicon carbide substrate; an epitaxial layer formed on the silicon carbide substrate; and a semiconductor element in which a current flows in a stacking direction of the silicon carbide substrate and the epitaxial layer.

### CROSS REFERENCE TO RELATED APPLICATION

This application is based on Japanese Patent Application No. 2023-008286 filed on Jan. 23, 2023, the disclosure of which is incorporated herein by reference.

### TECHNICAL FIELD

The present disclosure relates to a silicon carbide (SiC) substrate made of silicon carbide, a SiC wafer and a SiC semiconductor device.

### BACKGROUND

A SiC semiconductor device includes a semiconductor element such as a metal oxide semiconductor field effect transistor (MOSFET) using a SiC wafer in which an epitaxial layer of SiC is grown on a substrate formed of SiC.

### SUMMARY

According to a first aspect of the present disclosure, a SiC substrate has a Young's modulus of 475 GPa or more at 500° C. measured by a resonance method.

According to a second aspect of the present disclosure, a SiC wafer includes the SiC substrate and an epitaxial layer formed on the SiC substrate, and the epitaxial layer has a thickness within a range of 4 to 40 μm.

According to a third aspect of the present disclosure, a SiC semiconductor device includes: the SiC substrate; an epitaxial layer formed on the SiC substrate; and a semiconductor element in which a current flows along a stacking direction of the SiC substrate and the epitaxial layer.

### BRIEF DESCRIPTION OF DRAWINGS

FIG. 1 is a cross-sectional view of a SiC semiconductor device according to an embodiment.

FIG. 2 is a sectional view of a SiC wafer.

FIG. 3 is a diagram showing a warpage amount relative to each manufacturing step.

FIG. 4 is a diagram for explaining the warpage amount.

FIG. 5 is a graph showing a relationship between temperature and Young's modulus.

FIG. 6 is a diagram illustrating contaminant impurities in a substrate.

### DETAILED DESCRIPTION

A SiC semiconductor device includes a semiconductor element such as a metal oxide semiconductor field effect transistor (MOSFET) using a SiC wafer in which an epitaxial layer of SiC is grown on a substrate formed of SiC.

The SiC semiconductor device includes an n-type substrate, an n-type drift layer disposed on the substrate, a p-type base layer disposed on the drift layer, and an n-type source region formed in a surface layer portion of the base layer. The SiC semiconductor device includes a trench gate structure formed to penetrate the source region and reach the drift layer, a first electrode electrically connected to the base layer and the source region, and a second electrode connected to the substrate.

Such a SiC semiconductor device may be manufactured as follows. First, an n-type epitaxial layer is disposed on a substrate to form a SiC wafer. Next, ion implantation, activation annealing, and the like are performed to form a base layer, a source region, and the like, and a trench gate structure is formed. Thereafter, the SiC wafer is divided into chip units.

According to the study by the present inventor, it is confirmed that there is a possibility that warpage occurs in the SiC wafer when ion implantation, activation annealing, or the like is performed in manufacturing the SiC semiconductor device. If each manufacturing process is performed in a state where the warpage remains, the SiC wafer may be cracked or a characteristic defect of the SiC semiconductor device may occur.

The present disclosure provides a SiC substrate to suppress the occurrence of warpage, and a SiC wafer and a SiC semiconductor device using the SiC substrate.

According to a first aspect of the present disclosure, a SiC substrate has a Young's modulus of 475 GPa or more at 500° C. measured by a resonance method.

Accordingly, when a SiC wafer is formed by growing an epitaxial layer on a SiC substrate and a semiconductor device is manufactured using the SiC wafer, warpage of the SiC wafer can be suppressed.

According to a second aspect of the present disclosure, a SiC wafer includes the SiC substrate and an epitaxial layer formed on the SiC substrate, and the epitaxial layer has a thickness within a range of 4 to 40 μm.

Accordingly, since the SiC wafer is formed using the SiC substrate, warping of the SiC wafer can be suppressed when a semiconductor device is manufactured using the SiC wafer.

According to a third aspect of the present disclosure, a SiC semiconductor device includes: the SiC substrate; an epitaxial layer formed on the SiC substrate; and a semiconductor element in which a current flows along a stacking direction of the SiC substrate and the epitaxial layer.

Accordingly, since the SiC semiconductor device is configured using the SiC substrate, it is possible to suppress the occurrence of characteristic variation.

Hereinafter, an embodiment of the present disclosure will be described with reference to the drawings. In the following embodiments, the same or equivalent parts are denoted by the same reference numerals.

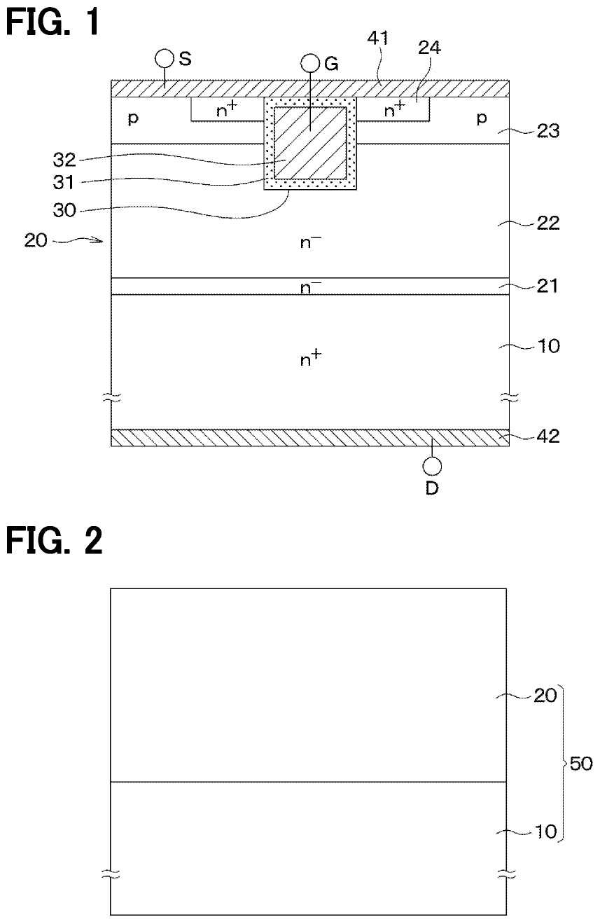

A SiC semiconductor device of an embodiment will be described with reference to FIG. 1. In the present embodiment, a SiC semiconductor device includes a MOSFET as a semiconductor element. Although not particularly illustrated, the SiC semiconductor device of the present embodiment includes a cell region and an outer peripheral region formed to surround the cell region. The MOSFET shown in FIG. 1 is formed in the cell region of the SiC semiconductor device.

The SiC semiconductor device includes a n-type substrate 10 made of SiC. An epitaxial layer 20 made of SiC is disposed on a surface of the substrate 10. The epitaxial layer 20 of the present embodiment has a buffer layer 21 of n⁻-type, a drift layer 22 of n⁻-type, and a base layer 23 of p-type stacked in this order. The epitaxial layer 20 of the present embodiment has a thickness of about 4 to 40 μm in a normal direction to the surface direction of the substrate 10, and has an impurity concentration of 1.0×10¹⁵ to 1.0×10¹⁹ cm⁻³.

A source region 24 of n⁺-type is disposed in a surface layer portion of the base layer 23. The base layer 23 and the source region 24 of the present embodiment are formed by ion implantation.

The substrate 10 has, for example, a specific resistance of 30 mΩ·cm or less, a (0001) Si surface, and an off angle within a range of 0.5 to 5° with respect to the (0001) Si surface. The substrate 10 has an n-type impurity concentration within a range of, for example, 5.0×10¹⁸ to 1.0×10²⁰ cm⁻³. The substrate 10 has a thickness of 300 to 600 μm. In the present embodiment, the substrate 10 corresponds to a silicon carbide substrate. In the present embodiment, the substrate 10 forms a drain layer of the MOSFET.

The buffer layer 21 has, for example, an n-type impurity concentration of 1.0×10¹⁸ to 1.0×10¹⁹ cm⁻³. The drift layer 22 has, for example, an n-type impurity concentration of 1.0×10¹⁵ to 5.0×10¹⁶ cm⁻³.

The base layer 23 has an area where a channel region is formed. The base layer 23 has, for example, a p-type impurity concentration of about 3.0×10 cm⁻³ and a thickness of 0.5 to 2 μm. The source region 24 has a higher impurity concentration than the drift layer 22. For example, an n-type impurity concentration in a surface layer portion of the source region 24 is about 2.5×10¹⁸ to 1.0×10¹⁹ cm⁻³, and the source region 24 has a thickness of 0.5 to 2 μm. The thickness of the drift layer 22, the base layer 23, or the source region 24 maybe suitably set and not limited to the above examples.

A trench 30 is formed so as to penetrate the base layer 23 and the source region 24 and reach the drift layer 22. The base layer 23 and the source region 24 are disposed so as to be in contact with a side surface of the trench 30. Although only one trench 30 is illustrated in FIG. 1, the trench 30 is actually formed in a stripe shape in which trenches are arranged at equal intervals in a left-right direction on a paper surface of FIG. 1.

A gate insulating film 31 is formed on a wall surface of the trench 30. A gate electrode 32 made of doped polysilicon is formed on a surface of the gate insulating film 31. The trench 30 is filled with the gate insulating film 31 and the gate electrode 32. In the present embodiment, a trench gate structure is configured in this manner.

An upper electrode 41 serving as a source electrode is disposed on the epitaxial layer 20. The upper electrode 41 is insulated from the gate electrode 32 and connected to the base layer 23 and the source region 24. Although not shown in FIG. 1, an interlayer insulating film is actually formed on the epitaxial layer 20, and the upper electrode 41 is connected to the base layer 23 and the source region 24 through a contact hole formed in the interlayer insulating film. The upper electrode 41 of the present embodiment is made of metals such as Ni/Al. A portion of the metals that is in contact with a portion forming an n-type SiC (that is, the source region 24) is made of a metal capable of making ohmic contact with the n-type SiC. In addition, at least a portion of the metals that is in contact with a portion forming a p-type SiC (that is, the base layer 23) is made of a metal capable of making ohmic contact with the p-type SiC.

A lower electrode 42 serving as a drain electrode is electrically connected to the substrate 10, and is formed on a rear surface of the substrate 10. In the present embodiment, with such a structure, MOSFET of an n-channel type inverted trench gate structure is formed. The cell region is formed by arranging plural MOSFETs.

The basic structure of the semiconductor device according to the present embodiment is described above. In such a SiC semiconductor device, when a predetermined gate voltage is applied to the gate electrode 32, an inversion layer is formed in a portion of the base layer 23 in contact with the trench 30, and a current flows between the upper electrode 41 and the lower electrode 42. That is, a current flows along the stacking direction of the substrate 10 and the epitaxial layer 20.

The SiC semiconductor device as described above is manufactured as follows.

First, as shown in FIG. 2, a wafer-like substrate 10 is prepared, and the epitaxial layer 20 is grown on the substrate 10 to form the SiC wafer 50. As the wafer- shaped substrate 10, for example, a substrate having a size of 6 inches is used, but a substrate having a size of 8 inches may be used. Next, although not shown in detail, ion implantation and activation annealing are performed on the epitaxial layer 20 to form the base layer 23, the source region 24, and the like so as to form a trench gate structure. Thereafter, the interlayer insulating film, the upper electrode 41, the lower electrode 42, and the like are formed, and the SiC wafer 50 is divided into chips, whereby the SiC semiconductor device is manufactured.

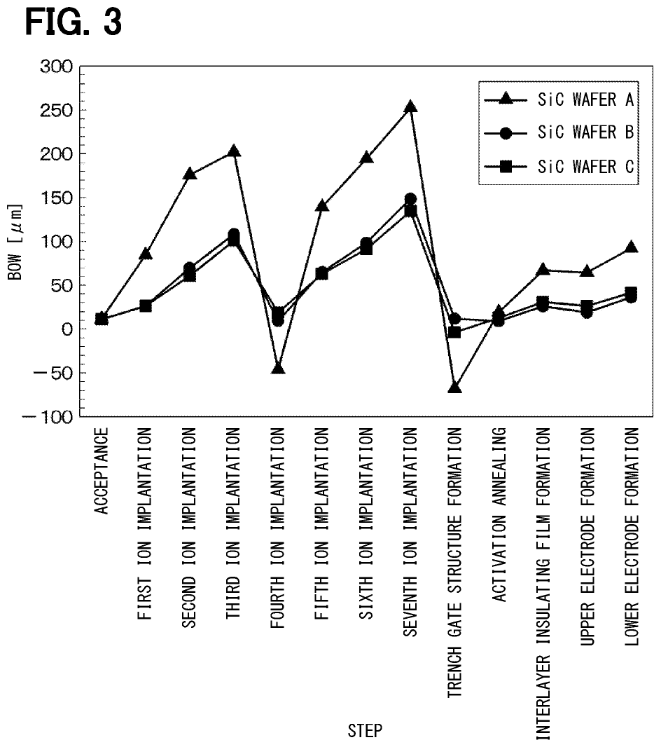

According to the study by the present inventor, it is confirmed that even when a manufacturing process such as ion implantation is performed under the same conditions, the amount of warpage may differ depending on the SiC wafer 50 to be used (that is, the substrate 10), as shown in FIG. 3. Note that the acceptance in FIG. 3 indicates that the SiC wafer 50 is disposed in a manufacturing apparatus, after the epitaxial layer 20 is disposed on the substrate 10. FIG. 3 shows a result obtained by preparing three samples of a SiC wafer A, a SiC wafer B, and a SiC wafer C, as the SiC wafer 50. FIG. 3 shows a result of performing ion implantation plural times (in FIG. 3, the first to seventh ion implantations are performed) when the base layer 23 and the source region 24 are formed.

In the results of FIG. 3, it was confirmed that the amount of warpage was larger when the manufacturing was performed using the SiC wafer A than when the manufacturing was performed using the SiC wafer B or the SiC wafer C.

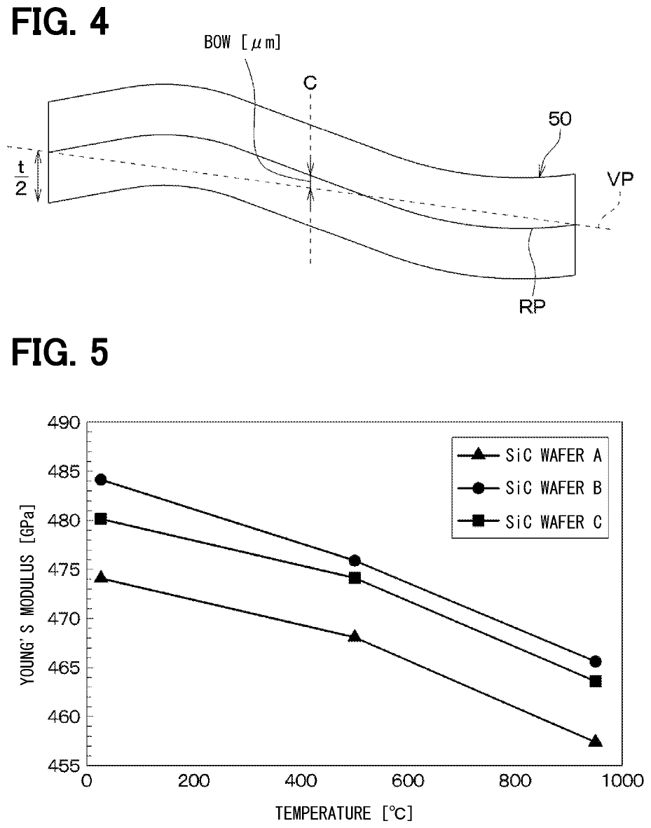

The warpage amount is a so-called BOW. Specifically, the following amount is defined as the warpage amount. As shown in FIG. 4, a plane continuously passing through the center (t/2) of the thickness t of the SiC wafer 50 is set as a reference plane

RP. In addition, a virtual plane VP is defined by connecting a left-end center (t/2) of the thickness t of the SiC wafer 50, which is one side of the SiC wafer 50, to a right-end center (t/2) of the thickness t of the SiC wafer 50, which is on the other side of the SiC wafer 50. The one side and the other side are opposite to each other with respect to the center C of the SiC wafer 50 in the surface direction. In the present embodiment, a distance between the reference plane RP and the virtual plane VP at the center C is defined as the warpage amount in a state where the SiC wafer 50 is held without being vacuum-sucked.

In this case, at present, it is desired that the warpage amount in each manufacturing step is 200 μm or less. Therefore, in the results of FIG. 3, the current requirements can be satisfied when the SiC wafer B and the SiC wafer C are used.

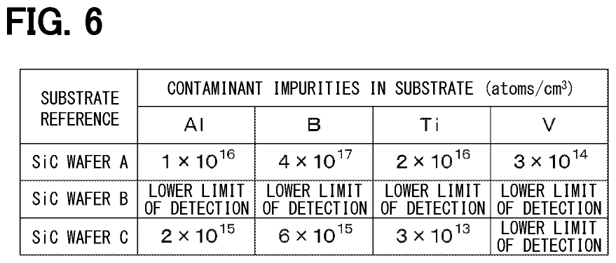

Further, the inventor diligently studied the warpage amount, and obtained the results shown in FIGS. 5 and 6. As shown in FIG. 5, when the Young's modulus was measured by a resonance method, it was confirmed that the Young's modulus of the SiC wafer A was smaller than those of the SiC wafers B and C. The measurement of the Young's modulus by the resonance method is a method of measuring the resonance frequency in a state where the sample is maintained at a constant temperature and deriving the Young's modulus based on the measured resonance frequency. In FIG. 5, the Young's modulus is measured in the state of the SiC wafer 50.

As shown in FIG. 6, it was confirmed that the SiC wafer A having a small Young's modulus contained more contaminant impurities than the SiC wafer B and the

SiC wafer C having a large Young's modulus. That is, FIGS. 5 and 6 confirm that the Young's modulus decreases as the amount of contaminant impurities contained in the substrate 10 increases. FIG. 6 shows the results of SIMS analysis, in which the lower limit of detection means that the amount of contaminant impurities is so small to be detected by the SIMS analysis. Contamination impurities are impurities that can be mixed when the substrate 10 is prepared, and currently, such as aluminum (Al), boron (B), titanium (Ti), and vanadium (V).

As described above, the SiC wafer B and the SiC wafer C can satisfy the current requirements. Therefore, from FIG. 5, it is sufficient that the substrate 10 has a Young's modulus of 475 GPa or more at 500° C. The substrate 10 mayhave a Young's modulus of 465 GPa or more at 1000° C. Further, from FIG. 6, it is sufficient that the substrate 10 has a total amount of contaminant impurities of 1.0×10¹⁶ atoms/cm³ or less. Therefore, the substrate 10 of the present embodiment satisfies these requirements. Note that 500° C. is a temperature at which crystal damage is maintained to be small when ion implantation is performed on the SiC wafer 50. 1000° C. is an upper limit temperature at which measurement accuracy is ensured in measurement of the Young's modulus in the current resonance method.

The substrate is usually obtained by cutting a SiC ingot. Specifically, the SiC ingot is obtained by a high temperature CVD (abbreviation of chemical vapor deposition) method or a sublimation method. More specifically, when a SiC ingot is manufactured by a high-temperature CVD method, a seed substrate made of SiC is disposed in a chamber, and a reaction gas such as silane or propane is introduced into the chamber to grow an epitaxial layer on the seed substrate while controlling the temperature in the chamber by a heating device disposed around the chamber. When the SiC ingot is manufactured, contaminant impurities in the chamber may be taken in. Therefore, in case of manufacturing a SiC ingot by a high temperature CVD method, it is preferable to use a high purity gas or to configure each member such as a chamber with a high purity material.

When a SiC ingot is manufactured by a sublimation method, a seed substrate made of SiC is disposed in a chamber, and an epitaxial layer is grown on the seed substrate by sublimating powder of SiC. When the SiC ingot is manufactured, contaminant impurities in the chamber and contaminant impurities in the powder may be taken in. Therefore, in case of manufacturing a SiC ingot by a sublimation method, it is preferable to use a high-purity powder or to configure each member such as a chamber with a high-purity material. Accordingly, the total amount of contaminant impurities contained in the substrate 10 can be easily set to 1.0×10¹⁶ atoms/cm or less.

When the SiC semiconductor device is manufactured, warping of the SiC wafer 50 during the manufacturing process can be suppressed by using the substrate 10 having a Young's modulus of 475 GPa or more at 500° C., in the resonance method.

The Young's modulus of the substrate 10 is preferably determined before the epitaxial layer 20 is grown. However, in the present embodiment, the substrate 10 has a thickness of about 300 μm to 600 μm, and the epitaxial layer has a thickness of about 4 to 40 μm. For this reason, since the influence of the epitaxial layer 20 is sufficiently small with respect to the influence of the substrate 10 and can be ignored, it may be performed after the epitaxial layer 20 is grown. FIG. 5 shows the result after growing the epitaxial layer 20.

In order to suppress warpage due to the Twyman effect, the substrate 10 maybe formed by polishing one side on which the epitaxial layer 20 is grown and the other side opposite to the one side by CMP (abbreviation of Chemical Mechanical Polishing) or the like. Further, the thickness of the substrate 10 is set to 300 to 600 μm, but may be set to be thick (for example, about 500 μm) in the range of 300 to 600 μm so as to be less likely to be warped.

According to the present embodiment, the substrate 10 has a Young's modulus of 475 GPa or more at 500° C. Therefore, when the SiC semiconductor device is manufactured, warping of the SiC wafer 50 can be suppressed. Therefore, it is possible to suppress the SiC wafer 50 from being cracked or the characteristics of the

SiC semiconductor device from being changed.

(1) In the present embodiment, since the substrate 10 has a Young's modulus of 465 GPa or more at 1000° C., it is possible to further suppress warping of the SiC wafer 50 in a high-temperature manufacturing process.

(2) In the present embodiment, the substrate 10 has contaminant impurities of 1×10¹⁶ atoms/cm³ or less. Therefore, when the SiC semiconductor device is manufactured, warping of the SiC wafer 50 can be suppressed. Therefore, it is possible to suppress the SiC wafer 50 from being cracked or the characteristics of the SiC semiconductor device from being changed.

(3) In the present embodiment, the thickness of the substrate 10 is 300 to 600 μm, and the specific resistance of the substrate 10 is 30 mΩ·cm or less. The n-type impurity concentration of the substrate 10 is 5.0×10¹⁸ to 1.0×10²⁰ cm⁻³. A part of the epitaxial layer 20 has a thickness of 4 to 40 μm and an impurity concentration of 1.0×10¹⁵ to 1.0×10¹⁹ cm⁻³. The buffer layer has an n-type impurity concentration of 1.0×10¹⁸ to 1.0×10¹⁹ cm⁻³, and the drift layer 22 has an n-type impurity concentration of 1.0×10¹⁵ to 5.0×10¹⁶ cm⁻³. Therefore, it is possible to obtain a MOSFET having currently desired characteristics.

### Other Embodiments

Although the present disclosure has been described in accordance with the embodiment, it is understood that the present disclosure is not limited to such embodiments or structures. The present disclosure encompasses various modifications and variations within the scope of equivalents. In addition, various combinations and configurations, as well as other combinations and configurations that include only one element, more, or less, fall within the scope and spirit of the present disclosure.

In the embodiment, the MOSFET has the n-channel type trench gate structure in which a first conductivity type is n-type and a second conductivity type is p-type. However, the semiconductor device may have a MOSFET with a p-channel type trench gate structure in which the conductivity type of each component is inverted with respect to the n-channel type.

In the embodiment, the SiC semiconductor device includes the MOSFET.

However, the SiC semiconductor device may include a Schottky diode, a pn diode, or an IGBT.

What is claimed is:

1. A silicon carbide substrate, comprising:
a substrate made of silicon carbide and having a Young's modulus of 475 GPa or more at 500° C. measured by a resonance method.

2. The silicon carbide substrate according to claim 1, wherein the substrate has a Young's modulus of 465 GPa or more at 1000° C. measured by a resonance method.

3. The silicon carbide substrate according to claim 1, wherein a contaminant impurity contained in the substrate is 1.0×10¹⁶ atoms/cm³ or less.

4. The silicon carbide substrate according to claim 1, wherein the substrate has a thickness within a range of 300 to 600 μm, a specific resistance of 30 mΩ·cm or less, and an n-type impurity concentration of 5.0×10¹⁸ to 1.0×10²⁰ cm⁻³.

5. A silicon carbide wafer comprising:
the silicon carbide substrate according to claim 1; and
an epitaxial layer formed on the silicon carbide substrate, wherein
the epitaxial layer has a thickness within a range of 4 to 40 μm.

6. The silicon carbide wafer according to claim 5, wherein a part of the epitaxial layer has an impurity concentration of 1.0×10¹⁵ to 1.0×10¹⁹ cm⁻³.

7. The silicon carbide wafer according to claim 6, wherein
the epitaxial layer includes: a buffer layer positioned adjacent to the silicon carbide substrate; and a drift layer positioned on the buffer layer,
the buffer layer has an n-type impurity concentration of 1.0×10¹⁸ to 1.0×10¹⁹ cm⁻³, and
the drift layer has an n-type impurity concentration of 1.0×10¹⁵ to 5.0×10¹⁶ cm⁻³.

8. A silicon carbide semiconductor device comprising:
the silicon carbide substrate according to claim 1;
an epitaxial layer formed on the silicon carbide substrate; and
a semiconductor element in which a current flows in a stacking direction of the silicon carbide substrate and the epitaxial layer.
